(19) United States
(12) Patent Application Publication
(10) Pub. No.: US 2025/0212635 A1
(43) Pub. Date: Jun. 26, 2025

(54) TRANSPARENT DISPLAY DEVICE

(71) Applicant: LG Display Co., Ltd., Seoul (KR)

(72) Inventors: Intae Ko, Paju-si (KR); Hyunjik Bae, Paju-si (KR); KwangHyun Baek, Paju-si (KR)

(73) Assignee: LG Display Co., Ltd., Seoul (KR)

(21) Appl. No.: 18/956,776

(22) Filed: Nov. 22, 2024

(30) Foreign Application Priority Data
Dec. 26, 2023 (KR) 10-2023-0191375

(51) Int. Cl. H10K 59/131; H10K 59/35; H10K 59/38; H10K 59/80

(52) U.S. Cl. CPC H10K 59/131; H10K 59/35; H10K 59/38; H10K 59/8792

(57) ABSTRACT

A transparent display device in one example includes a substrate having transmissive areas configured to transmit an external light and a non-transmissive area disposed between adjacent transmissive areas, and a light emitting device disposed in the non-transmissive area on the substrate. Each of the transmissive areas includes a plurality of straight portions and a plurality of corner portions connecting the plurality of straight portions. Each of the plurality of corner portions has a step shape in plan view.

### CROSS-REFERENCE TO RELATED APPLICATIONS

This application claims priority to Korean Patent Application No. 10-2023-0191375, filed in the Republic of Korea on Dec. 26, 2023, the entire contents of which are hereby expressly incorporated by reference into the present application.

### BACKGROUND

### Technical Field

The present disclosure relates to a transparent display device having a transmissive area within a display area.

### Discussion of the Related Art

With advancement in information-oriented societies, demands for display devices that display an image have increased in various forms. Various types of display devices such as a liquid crystal display (LCD) device, a plasma display panel (PDP) device, a Quantum dot Light Emitting Display (QLED), and an organic light emitting display (OLED) device have been widely utilized.

In recent years, there has been active research on the display devices that allow users to view objects or images located on the rear surface of the display device. A transparent display device can include a display area where images are displayed and a non-display area adjacent to the display area. The display area can include a transmissive area that can transmit external light and a non-transmissive area. In the transparent display device, the light transmittance of the display area can be determined according to the light transmittance of the transmissive area.

### SUMMARY OF THE DISCLOSURE

The present disclosure is directed to providing a transparent display device, which substantially obviate one or more problems due to limitations and disadvantages of the related art.

An aspect of the present disclosure is directed to providing a transparent display device having a high light transmittance.

Another aspect of the present disclosure is directed to providing a transparent display device having a high transparency purity.

Another aspect of the present disclosure is directed to providing a transparent display device, which are capable of realizing ESG (Environment/Social/Governance) by reducing the generation of greenhouse gases due to the manufacturing process for producing the transparent display device.

Additional advantages and features of the disclosure will be set forth in part in the description which follows and in part will become apparent to those having ordinary skill in the art upon examination of the following or can be learned from practice of the disclosure. Other benefits of the disclosure can be realized and attained by the structure particularly pointed out in the written description and claims hereof as well as the appended drawings.

To achieve these and other advantages and in accordance with the purpose of the disclosure, as embodied and broadly described herein, there is provided a transparent display device including a substrate including transmissive areas that transmit an external light and a non-transmissive area disposed between adjacent transmissive areas; and a light emitting device disposed in the non-transmissive area on the substrate, wherein each of the transmissive areas comprises a plurality of straight portions and a plurality of corner portions connecting the plurality of straight portions, and wherein each of the plurality of corner portions has a step shape in plan view.

In another aspect of the present disclosure, there is provided a transparent display device including transmissive areas transmitting an external light and a non-transmissive area disposed between adjacent transmissive areas; a first signal line extended in a first direction in the non-transmissive area; and a second signal line extended in a second direction in the non-transmissive area, wherein each of the transmissive areas comprises: a plurality of straight portions disposed to face each of the first signal line and the second signal line; and a plurality of corner portions disposed to have a step shape while facing an area where the first signal and the second signal line are overlapped.

In yet another aspect of the present disclosure, there is provided a transparent display device, comprising: transmissive areas that transmit an external light; a non-transmissive area disposed between adjacent transmissive areas; and a first sub-pixel, a second sub-pixel and a third sub-pixel disposed in the non-transmissive area, wherein each of the transmissive areas comprises a plurality of straight portions and a plurality of corner portions connecting the plurality of straight portions, each corner portion having a step shape in plan view, and wherein sides of the transmissive areas facing the non-transmissive area disposed between the first sub-pixel and the third sub-pixel are straight portions. The first sub-pixel emits a light of a first color, a second sub-pixel emits a light of a second color, and a third sub-pixel emits a light of a third color.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a perspective view schematically illustrating a transparent display device according to one or more embodiments of the present disclosure;

FIG. 2 is a plan view schematically illustrating a transparent display panel according to one or more embodiments of the present disclosure;

FIG. 3 schematically illustrates an example of a pixel disposed in a region A illustrated in FIG. 2;

FIG. 4 is an example of a circuit diagram of a subpixel illustrated in FIG. 3;

FIG. 5 is a cross-sectional view illustrating an example of the elements disposed in the non-transmissive area and the transmissive area illustrated in FIG. 3;

FIG. 6 illustrates an example of a non-transmissive area according to one or more embodiments of the present disclosure;

FIG. 7 illustrates an example of a transmissive area according to one or more embodiments of the present disclosure; and

FIG. 8 illustrates an example of a circular transmissive area according to one or more aspects of the present disclosure.

### DETAILED DESCRIPTION OF THE EMBODIMENTS

Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus the present disclosure is not limited to the illustrated details. Like reference numerals refer to like elements throughout. In the following description, when the detailed description of the relevant known technology is determined to unnecessarily obscure the important point of the present disclosure, the detailed description will be omitted. In a case where “comprise,” “have,” and “include” described in the present disclosure are used, another part can be added unless “only” is used. The terms of a singular form can include plural forms unless referred to the contrary.

In construing an element, the element is construed as including an error range although there is no explicit description.

In describing a positional relationship, for example, when a position relation between two parts is described as “on”, “over”, “under”, and “next”, one or more other parts can be disposed between the two parts unless “just” or “direct” is used.

In describing a temporal relationship, for example, when a temporal precedence relationship is described such as “after”, “following”, “next”, “before”, etc., it can include cases that are not consecutive unless “immediately” or “directly” are used.

It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item. Further, the term “can” fully encompasses all the meanings and coverages of the term “may.”

Features of various embodiments of the present disclosure can be partially or totally coupled to or combined with each other, and can be variously inter-operated and driven technically. The embodiments of the present disclosure can be carried out independently from each other or can be carried out together with a co-dependent relationship.

Hereinafter, with reference to the accompanying drawings, one example of a display device according to the present disclosure is described. In assigning reference numerals to the components in each drawing, the same component can have the same numeral as far as possible, even if it is shown in different drawings. In addition, when the detailed description of the relevant known technology is determined to unnecessarily obscure the important point of the present disclosure, the detailed description will be omitted.

Hereinafter, with reference to the accompanying drawings, one or more embodiments of the present disclosure will be described. All the components of each display device according to all embodiments of the present disclosure are operatively coupled and configured.

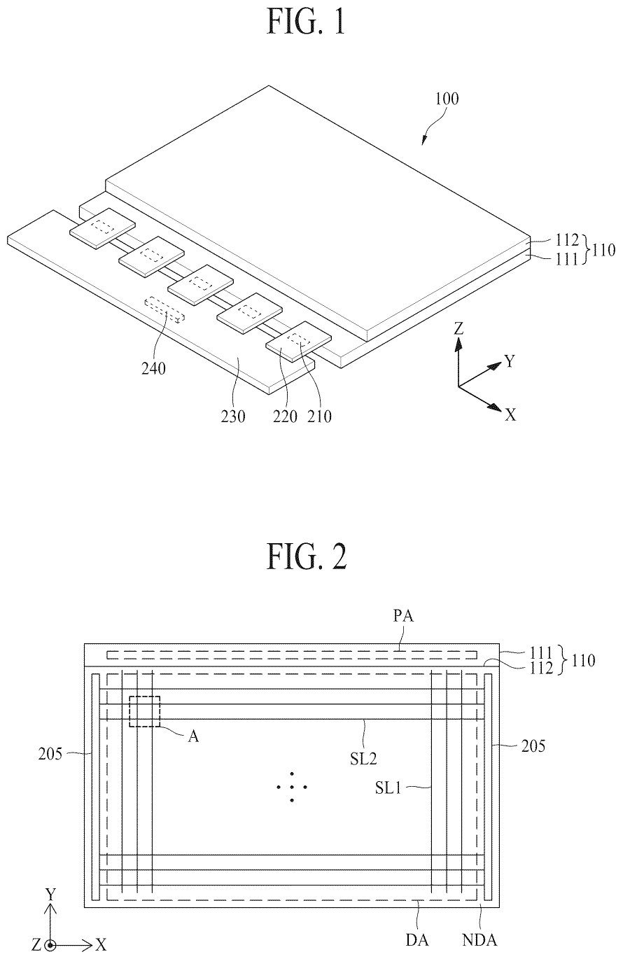

FIG. 1 is a perspective view schematically illustrating a transparent display device according to one or more embodiments of the present disclosure, and FIG. 2 is a plan view schematically illustrating a transparent display panel according to one or more embodiments of the present disclosure.

Hereinafter, in an example, an X axis represents a direction parallel to a scan line, a Y axis represents a direction parallel to a data line, and a Z axis represents a height direction of a transparent display device 100. However, other variations are possible.

An example where the transparent display device 100 according to one or more embodiments of the present disclosure is implemented as an organic light emitting display apparatus will be mainly described, but the transparent display device 100 can be implemented as a liquid crystal display (LCD) apparatus, a quantum dot light emitting display (OLED) apparatus, or an electrophoresis display apparatus.

Referring to FIGS. 1 and 2, the transparent display device 100 according to one or more embodiments of the present disclosure can include a transparent display panel 110, a source driver integrated circuit (IC) 210, a flexible film 220, a circuit board 230, and a timing controller 240.

The transparent display panel 110 includes a first substrate 111 and a second substrate 112 facing each other. The second substrate 112 can be an encapsulation substrate. The first substrate 111 can be a plastic film, a glass substrate, or a silicon wafer substrate formed using a semiconductor process. The second substrate 112 can be a plastic film, a glass substrate, or an encapsulation film. The first substrate 111 and the second substrate 112 can be made of a transparent material.

The transparent display panel 110 can be divided into a display area DA (or active area) and a non-display area NDA (or non-active area). The display area DA includes a plurality of pixels P and displays images. The non-display area NDA does not display the images, and can surround the display area DA entirely or only in part.

The display area DA can include first signal lines SL1, second signal lines SL2, and pixels P. The non-display area NDA can include a pad area PA with pads disposed thereon and at least one scan driver 205.

The first signal lines SL1 can extend in a first direction (e.g., in a Y axis direction) and can intersect the second signal lines SL2 in the display area DA. The second signal lines SL2 can extend in the display area DA in a second direction (e.g., in a X axis direction). The pixels are disposed in an area in which the first signal SL1 is disposed or an area in which the first signal line SL1 and the second signal line SL2 intersect, and emit a predetermined light to display images.

A plurality of pads can be disposed in the pad area PA. Since the size of the first substrate 111 is larger than the size of the second substrate 112, a portion of the first substrate 111 can be exposed and not covered by the second substrate 112. The pads such as power pads or data pads, etc., can be disposed in the portion of the first substrate 111 that is exposed and not covered by the second substrate 112.

The scan driver 205 is connected to the scan line to supply a scan signal. The scan driver 205 can be formed in a gate driver in panel GIP type in the non-display area NDA outside of one side or both sides of the display area DA. Alternatively, the scan driver 205 can be fabricated as a driver chip, mounted on a flexible film, and attached to the non-display area NDA outside of one side or both sides of the display area DA in tape automated bonding TAB type.

The source driver IC 210 receives a digital video data and a data control signal from the timing controller 240. The source driver IC 210 converts the digital video data into analog data voltages according to the data control signal and supplies them to the data lines. If the source driver IC 210 is fabricated as a driver chip, it can be mounted on the flexible film 220 in a chip on film COF type or a chip on plastic COP type.

The flexible film 220 can include wires connecting the pads to the source driver IC 210 and wires connecting the pads to the wires of the circuit board 230. The flexible film 220 can be attached on the pads using an anisotropic conducting film, thereby connecting the wires of the pads and the flexible film 220.

The circuit board 230 can be attached to the flexible films 220. The circuit board 230 can have a plurality of circuits implemented with driving chips mounted thereon. For example, the timing controller 240 can be mounted on the circuit board 230. The circuit board 150 can be a printed circuit board or a flexible printed circuit board.

The timing controller 240 receives the digital video data and a timing signal from an external system board. The timing controller 240 generates a scan control signal for controlling the operation timing of the scan driver and a data control signal for controlling the source driver ICs 210 based on the timing signal. The timing controller 240 supplies the scan control signal to the scan driver 205 and the data control signal to the source driver ICs 210.

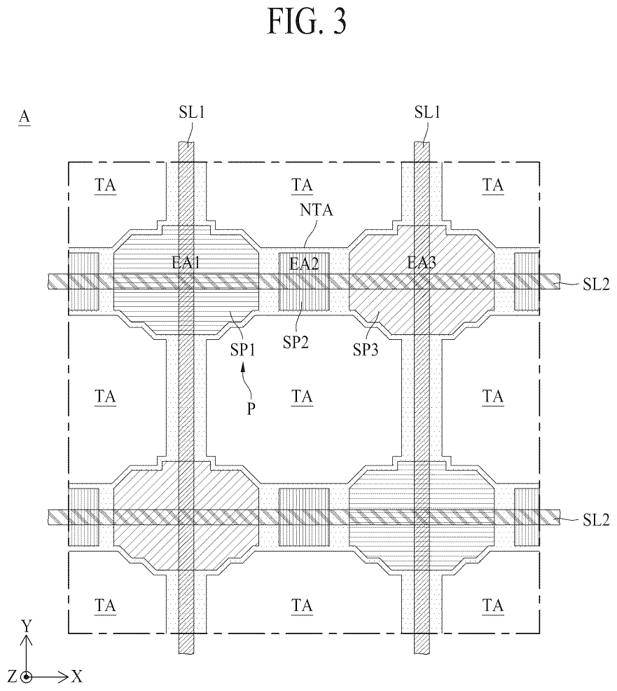

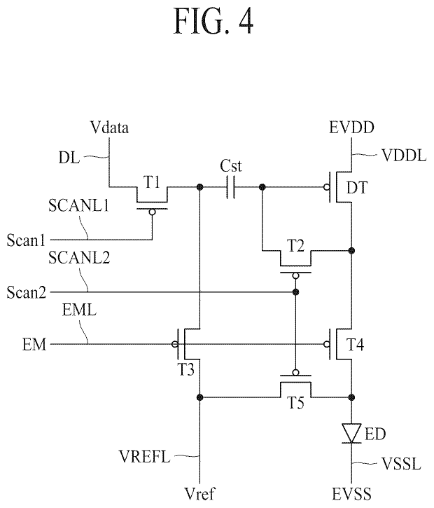

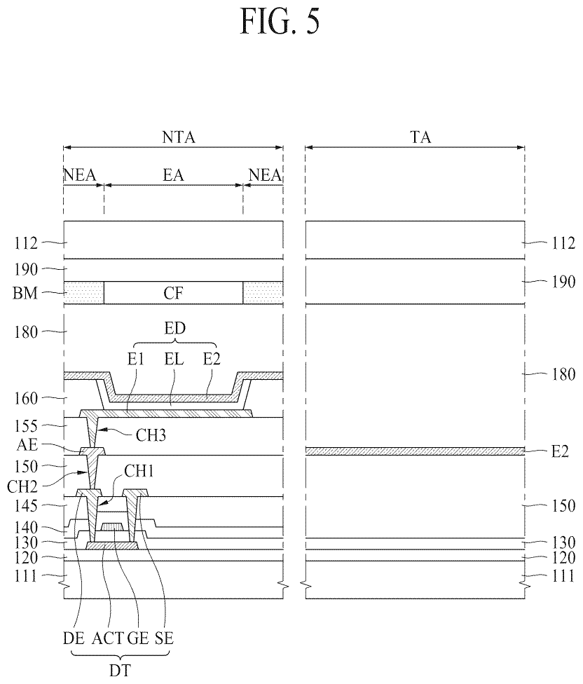

FIG. 3 schematically illustrates an example of pixel disposed in a region A illustrated in FIG. 2, FIG. 4 is an example of a circuit diagram of a subpixel illustrated in FIG. 3, and FIG. 5 is a cross-sectional view illustrating an example of the elements disposed in the non-transmissive area and the transmissive area illustrated in FIG. 3.

Referring to FIGS. 3-5, the transparent display panel 110 according to one or more embodiments of the present disclosure can include the display area DA and the non-display area NDA (see FIG. 2).

As illustrated in FIG. 3, the display area DA can include a first area NTA in which a plurality of sub-pixels SP1, SP2, and SP3 are disposed, and a second area TA in which a plurality of sub-pixels SP1, SP2 and SP3 are not disposed. The first area NTA can be a non-transmissive area in which most of the light incident from the outside is not transmitted, and the second area TA can be a transmissive area in which most of the light incident from the outside is transmitted.

For example, the transmissive area TA can be an area having a light transmittance greater than x %, and the non-transmissive area NTA can be an area having a light transmittance less than B %. In this example, a can be a value greater than B, and each of a and B can be a positive number. The transparent display panel 110 can allow viewing of an object or background scenes that are located at a rear surface of the transparent display panel 110 due to the transmissive areas TA.

In the non-transmissive area NTA, the plurality of sub-pixels SP1, SP2, and SP3, a plurality of circuit elements, and a plurality of signal lines SL1 and SL2 can be disposed so that the light incident from the outside cannot pass through.

The plurality of signal lines can include the first signal lines SL1 and the second signal lines SL2. The first signal lines SL1 can be extended in the first direction (e.g., the Y axis direction) in the non-transmissive area NTA. The first signal lines SL1 can include a pixel power line, a data line, and a common power line. In an example embodiment, the first signal lines SL1 can further include a reference line.

The pixel power line can supply a first power to a driving transistor of each of the sub-pixels SP1, SP2, and SP3. The common power line can supply a second power to a cathode electrode of the sub-pixels SP1, SP2, and SP3. In this example, the second power can be a common power commonly supplied to the sub-pixels SP1, SP2, and SP3. In addition, the common power line can be spaced apart from the pixel power line with the transmissive area TA interposed therebetween.

The reference line can supply an initialization voltage (or a reference voltage) to the driving transistor of each of the sub-pixels SP1, SP2, and SP3. Each of the data lines can supply the data voltage to the sub-pixels SP1, SP2, and SP3.

The second signal lines SL2 can be extended in the non-transmissive area NTA in the second direction (e.g., in the X axis direction). The second signal lines SL2 can include the scan line. The scan line can supply the scan signal to the sub-pixels SP1, SP2, and SP3.

Each of the sub-pixels SP1, SP2, and SP3 is disposed in the non-transmissive area NTA and emits light to display images. An emission area EA can correspond to an area where the sub-pixels SP1, SP2, and SP3 can emit light.

The sub-pixels SP1, SP2, and SP3 can be any one of a first sub-pixel SP1 that emits light of a first color, a second sub-pixel SP2 that emits light of a second color, and a third sub-pixel SP3 that emits light of a third color, but are not necessarily limited thereto. The pixel P can include at least two of sub-pixels SP1, SP2, and SP3. For example, the pixel P can include the first sub-pixel SP1, the second sub-pixel SP2, and the third sub-pixel SP3. In another example, one pixel P can include the first sub-pixel SP1 and the second sub-pixel SP2, and the other pixel P can include the second sub-pixel SP2 and the third sub-pixel SP3. Each pixel P can further include a fourth sub-pixel that emits white light.

The first sub-pixel SP1 can include a first emission area EA1 that emits the first color light, the second sub-pixel SP2 can include a second emission area EA2 that emits the second color light, and the third sub-pixel SP3 can include a third emission area EA3 that emits the third color light. However, the present disclosure is not limited thereto. When each pixel P further includes the fourth sub-pixel that emits white light, the fourth sub-pixel can include a fourth emission area that emits white light.

For example, all of the first to third emission areas EA1, EA2, and EA3 can emit light of different colors. For example, the first emission area EA1 can emit blue light, the second emission area EA2 can emit red light, and the third emission area EA3 can emit green light. The arrangement order of each of the sub-pixels SP1, SP2, and SP3 can be variously changed.

Each of the first sub-pixel SP1, the second sub-pixel SP2, and the third sub-pixel SP3 can include a circuit element and a light emitting device. Referring to FIG. 4, each of the sub-pixels SP1, SP2, and SP3 can include a pixel circuit including a plurality of transistors DT and T1 to T5, and the light emitting device ED.

The pixel circuit illustrated in FIG. 4 can include five switching transistors T1 to T5, the driving transistor DT, a storage capacitor Cst, and the light emitting device ED, but is not limited thereto.

Each of the transistors DT and T1 to T5 of each of the sub-pixels SP1, SP2, and SP3 can include a gate electrode, a source electrode, and a drain electrode. Since the source electrode and the drain electrode are not fixed and can be changed according to the voltage and current direction applied to the gate electrode, one of the source electrode and the drain electrode can be expressed as a first electrode, and the other can be expressed as a second electrode. The transistors DT and T1 to T5 of each of the sub-pixels SP1, SP2, and SP3 can use at least one of a polysilicon semiconductor, an amorphous silicon semiconductor, and an oxide semiconductor. The transistors can be P-type, N-type, or a mixture of P-type and N-type.

The first electrode of the driving transistor DT can be connected to the pixel power line VDDL supplying the first power voltage EVDD. The second electrode of the driving transistor DT can drive the light emitting device ED through the fourth switching transistor T4. The driving transistor DT can control a driving current according to a driving voltage Vg of the storage capacitor Cst. Accordingly, the driving transistor DT can control the light emission intensity of the light emitting device ED.

The storage capacitor Cst can charge the driving voltage Vg corresponding to the data voltage Vdata. The storage capacitor Cst can supply the charged driving voltage Vg to the driving transistor DT.

The first switching transistor T1 can be turned on or turned off in response to a first scan signal Scan1 supplied to a first scan line SCANL1. The first switching transistor T1 can supply the data voltage Vdata supplied through the data line DL to a first electrode of the storage capacitor Cst in response to a gate-on voltage of the first scan signal Scan1.

The second and fifth switching transistors T2 and T5 can be turned on or turned off in response to a second scan signal Scan2 supplied to a second scan line SCANL2. The second switching transistor T2 can connect the gate electrode and the second electrode of the driving transistor DT in response to a gate-on voltage of the second scan signal Scan2, thereby connecting the driving transistor DT in a diode structure. The second switching transistor T2 can compensate for the threshold voltage Vth of the driving transistor DT by charging the threshold voltage Vth in the storage capacitor Cst. Accordingly, the storage capacitor Cst can charge the data voltage Vdata+Vth for which the threshold voltage Vth of the driving transistor DT is compensated.

The fifth switching transistor T5 can supply an initialization voltage Vref (or reference voltage) supplied through an initialization voltage line VREFL (or the reference line) to the anode electrode of the light emitting device ED in response to the gate-on voltage of the second scan signal Scan2.

The third and fourth switching transistors T3 and T4 can be turned on or turned off in response to an emission control signal EM supplied to an emission control line EML. The third switching transistor T3 can supply the initialization voltage Vref (or reference voltage) supplied through the initialization voltage line VREFL (or the reference line) to the first electrode of a storage capacitor Cst in response to a gate-on voltage of the emission control signal EM.

The fourth switching transistor T4 can connect the driving transistor DT and the light emitting device ED in response to the gate-on voltage of the emission control signal EM. The light emitting device ED can have an anode electrode, a cathode electrode supplied with the second power voltage EVSS from the common power line VSSL, and a light emitting layer between the anode electrode and the cathode electrode. When the driving current is supplied from the driving transistor DT through the fourth switching transistor T4 to the light emitting device ED, electrons are injected from the cathode electrode into the light emitting layer, holes are injected from the anode electrode into the light emitting layer to emit fluorescent material or phosphorescent material by recombination of the electrons and the holes in the light emitting layer, thereby generating light with a brightness proportional to a value of the driving current.

Hereinafter, elements disposed in the non-transmissive area NTA and the transmissive area TA will be described in more detail with reference to FIG. 5.

Referring to FIG. 5, the transparent display panel 110 according to one or more examples of the present disclosure includes a first substrate 111 and a second substrate 112 facing each other. A circuit element, the light emitting device ED, an encapsulation layer 180, a color filter CF, and a black matrix BM can be disposed between the first substrate 111 and the second substrate 112.

The circuit element can include various signal lines, thin-film transistor, and capacitor, etc. The signal lines can include the pixel power lines, the common power lines, the scan lines, the data lines, etc. The thin film transistor can include the switching transistor and the driving transistor DT. The switching transistor can be switched according to the scan signal supplied to the scan line to charge the capacitor Cst with the data voltage supplied from the data line.

The driving transistor DT can be switched according to the data voltage charged in the capacitor Cst (see FIG. 4). The driving transistor DT generates the data current from the power supplied from the pixel power line VDDL (see FIG. 4) and supplies the data current to the first electrode E1 of each of the subpixels SP1, SP2, and SP3. The driving transistor DT can include an active layer ACT, a gate electrode GE, a source electrode SE, and a drain electrode DE.

Specifically, a buffer layer 120 can be disposed on the first substrate 111. The buffer layer 120 can protect the driving transistor DT from moisture penetrating through the first substrate 111 that is vulnerable to moisture permeation. To this end, the buffer layer 120 can be disposed in the non-transmissive area NTA and the transmissive area TA. The buffer layer 120 can be formed of an inorganic layer, for example, a silicon oxide layer SiOx, a silicon nitride layer SiNx, or multiple layers thereof.

The active layer ACT of the driving transistor DT can be disposed on the buffer layer 120. The active layer ACT of the driving transistor DT can be formed of a silicon-based semiconductor material or an oxide-based semiconductor material.

A gate insulating layer 130 can be disposed on the active layer ACT of the driving transistor DT. The gate insulating layer 130 can be disposed in the non-transmissive area NTA and the transmissive area TA. The gate insulating layer 130 can be formed of an inorganic layer, for example, a silicon oxide layer SiOx, a silicon nitride layer SiNx, or multiple layers thereof.

The gate electrode GE of the driving transistor DT can be disposed on the gate insulating layer 130. The gate electrode GE of the driving transistor DT can be formed as a single layer or multiple layers made of any one or an alloy of molybdenum Mo, aluminum Al, chromium Cr, gold Au, titanium Ti, nickel Ni, neodymium Nd, and copper Cu.

A first interlayer insulating layer 140 and a second interlayer insulating layer 145 can be disposed on the gate electrode GE of the driving transistor DT. In order to increase the light transmittance of the transmissive area TA, the first interlayer insulating layer 140 and the second interlayer insulating layer 145 can be disposed only in the non-transmissive area NTA, and cannot be disposed in the transmissive area TA. Each of the first interlayer insulating layer 140 and the second interlayer insulating layer 145 can be formed of an inorganic layer, for example, a silicon oxide layer SiOx, a silicon nitride layer SiNx, or multiple layers thereof.

The source electrode SE and the drain electrode DE of the driving transistor DT can be disposed on the second interlayer insulating layer 145. Each of the source electrode SE and the drain electrode DE of the driving transistor DT can be connected to the active layer ACT of the driving transistor DT through a first contact hole CH1 penetrating the gate insulating layer 130, the first interlayer insulating layer 140, and the second interlayer insulating layer 145. The source electrode SE and the drain electrode DE of the driving transistor DT can be formed as a single layer or multiple layers made of any one or an alloy of molybdenum Mo, aluminum Al, chromium Cr, gold Au, titanium Ti, nickel Ni, neodymium Nd, and copper Cu.

A first planarization layer 150 can be disposed on the source electrode SE and the drain electrode DE of the driving transistor DT to planarize the step difference caused by the driving transistor DT. The first planarization layer 150 can be formed of an organic layer such as an acrylic resin, an epoxy resin, a phenolic resin, a polyamide resin, or a polyimide resin.

An auxiliary electrode AE can be disposed on the first planarization layer 150. The auxiliary electrode AE can be connected to one of the source electrode SE and the drain electrode DE of the driving transistor DT through a second contact hole CH2 penetrating the first planarization layer 150. The auxiliary electrode AE can be formed as a single layer or multiple layers made of any one or an alloy of molybdenum Mo, aluminum Al, chromium Cr, gold Au, titanium Ti, nickel Ni, neodymium Nd, and copper Cu.

A second planarization layer 155 can be formed on the auxiliary electrode AE. The second planarization layer 155 can be formed of an organic film such as an acrylic resin, an epoxy resin, a phenolic resin, a polyamide resin, or a polyimide resin.

At least one of the first planarization layer 150 and the second planarization layer 155 can be disposed in the non-transmissive area NTA and cannot be disposed in at least a part of the transmissive area TA.

In the transparent display panel 110 according to the one example of the present disclosure, at least one of the first planarization layer 150 and the second planarization layer 155 cannot be disposed in the transmissive area TA, thereby improving the light transmittance of the transmissive area TA.

The light emitting device ED and a bank 160 can be disposed on the second planarization layer 155. The light emitting device ED can include a first electrode E1, a light emitting layer EL, and a second electrode E2.

The first electrode E1 can be disposed on the second planarization layer 155 and can be electrically connected to the driving transistor DT. In detail, the first electrode E1 can be connected to the auxiliary electrode AE through a third contact hole CH3 penetrating the second planarization layer 155. Since the auxiliary electrode AE is connected to one of the source electrode SE and the drain electrode DE of the driving transistor DT through the second contact hole CH2, the first electrode E1 can be connected to one of the source electrode SE and the drain electrode DE of the driving transistor DT through the auxiliary electrode AE.

The first electrode E1 can be disposed for each of the subpixels SP1, SP2, and SP3, and cannot be disposed in the transmissive area TA. The bank 160 can be disposed between the first electrodes E1 adjacent to each other, and thus the first electrodes E1 adjacent to each other can be electrically insulated from each other.

The first electrode E1 can be formed of a highly reflective metal material such as a stacked structure of aluminum and titanium (Ti/Al/Ti), a stacked structure of aluminum and ITO (ITO/AI/ITO), an Ag alloy, a stacked structure of Ag alloy and ITO (ITO/Ag alloy/ITO), a MoTi alloy, and a stacked structure of the MoTi alloy and ITO (ITO/MoTi alloy/ITO). The Ag alloy can be an alloy such as silver Ag, palladium Pd, copper Cu, etc. The MoTi alloy can be an alloy of molybdenum Mo and titanium Ti. The first electrode E1 can be an anode electrode.

The bank 160 can be disposed on the second planarization layer 155. The bank 160 can be formed to cover an edge of the first electrode E1 and expose a part of the first electrode E1. Accordingly, the bank 160 can prevent a problem in which the light emission efficiency is deteriorated due to the concentration of current on the end of the first electrode E1.

The bank 160 can define emission areas EA1, EA2 and EA3 of each of the subpixels SP1, SP2, and SP3. The emission areas EA1, EA2, and EA3 of each of the subpixels SP1, SP2, and SP3 represent areas in which the first electrode E1, the light emitting layer EL, and the second electrode E2 are sequentially stacked so that holes from the first electrode E1 and electrons from the second electrode E2 are coupled to each other in the light emitting layer EL to emit light. In this example, an area in which the bank 160 is disposed does not emit light and thus becomes the non-emission area NEA, and an area in which the bank 160 is not disposed and the first electrode E1 is exposed can be the emission areas EA1, EA2, and EA3. The bank 160 can be disposed in the non-transmissive area NTA, and cannot be disposed in at least a portion of the transmissive area TA.

The bank 160 can be formed of an organic layer such as an acryl-based material, an epoxy-based material, a phenolic-based material, a polyamide-based material, and a polyimide-based material, etc.

The light emitting layer EL can be disposed on the first electrode E1. The light emitting layer EL can include an emission material layer EML including a light emitting material. The light emitting material can include an organic material, an inorganic material, or a hybrid material. The light emitting layer EL can have a multilayer structure. For example, the light emitting layer EL can further include at least one of a hole injection layer HIL, a hole transport layer HTL, an electron transport layer ETL, and an electron injection layer EIL. In this example, when a voltage is applied to the first electrode E1 and the second electrode E2, holes and electrons move to the emission material layer EML through the hole transport layer HTL and the electron transport layer ETL, respectively, and combines with each other in the emission material layer EML to emit light.

In one or more embodiments, the light emitting layer EL can be a common layer commonly formed in the subpixels SP1, SP2, and SP3. In this example, the light emitting layer EL can be a white light emitting layer emitting white light. In this example, the light emitting layer EL can be formed not only in the subpixels SP1, SP2, and SP3, but also in the non-emission area NEA between the subpixels SP1, SP2, and SP3. The light emitting layer EL can be continuously formed between the subpixels SP1, SP2, and SP3. The light emitting layer EL can be disposed in the transmissive area TA as well as the non-transmissive area NTA including the emission areas EA1, EA2, and EA3 and the non-emission area NEA, but it is not limited thereto. The light emitting layer EL can be patterned only in the non-transmissive area NTA including the emission areas EA1, EA2, and EA3 and the non-emission area NEA.

In another example embodiment, as shown in FIG. 5, the emission material layer EML of the light emitting layer EL can be formed for each of the subpixels SP1, SP2, and SP3. For example, a blue light emitting layer emitting blue light can be formed in the first subpixel SP1, a red light emitting layer emitting red light can be formed in the second subpixel SP2, and a green light emitting layer emitting green light can be formed in the third subpixel SP3. In this example, the emission material layer EML of the light emitting layer EL cannot be formed in the transmissive area TA. However, the hole injection layer HIL, the hole transport layer HTL, the electron transport layer ETL, and the electron injection layer EIL except for the emission material layer EML can be formed in common in the subpixels SP1, SP2, and SP3, and can also be formed in the transmissive area TA.

The second electrode E2 can be disposed on the light emitting layer EL. The second electrode E2 can be a common layer commonly formed in the subpixels SP1, SP2, and SP3. The second electrode E2 can be formed not only in the emission areas EA1, EA2, and EA3 of the subpixels SP1, SP2, and SP3, but also in the non-emission area NEA between the subpixels SP1, SP2, and SP3. The second electrode E2 can be continuously formed in the sub-pixels SP1, SP2, and SP3, and between the subpixels SP1, SP2, and SP3.

The second electrode E2 can be formed of a transparent metal material TCO such as ITO or IZO capable of transmitting light, or a semi-transmissive conductive material such as magnesium Mg, silver Ag, or an alloy of magnesium Mg and silver Ag. When the second electrode E2 is formed of the semi-transmissive conductive material, light emission efficiency can be increased due to a micro cavity. The second electrode E2 can be a cathode electrode.

The encapsulation layer 180 can be disposed on the light emitting devices ED. The encapsulation layer 180 can be formed on the second electrode E2 to cover the second electrode E2. The encapsulation layer 180 serves to prevent oxygen or moisture from penetrating into the light emitting layer EL and the second electrode E2. To this end, the encapsulation layer 180 can include at least one inorganic layer and at least one organic layer. The encapsulation layer 180 can have a structure in which an inorganic layer and an organic layer are alternately stacked, but it is not limited thereto.

A color filter CF can be disposed on the encapsulation layer 180. The color filter CF can be patterned for each of the subpixels SP1, SP2, and SP3. Specifically, the color filter CF can include a first color filter, a second color filter, and a third color filter. The first color filter can be disposed to correspond to the emission area EA1 of the first subpixel SP1, and can be a blue color filter that transmits blue light. The second color filter can be disposed to correspond to the emission area EA2 of the second subpixel SP2, and can be a red color filter that transmits red light. The third color filter can be disposed to correspond to the emission area EA3 of the third subpixel SP3, and can be a green color filter that transmits green light.

The transparent display panel 110 according to one example embodiment of the present disclosure can include the color filter CF without using a polarizing plate. When the polarizing plate is attached to the transparent display panel 110, the transmittance of the transparent display panel 110 can decrease due to the polarizing plate. On the other hand, when the polarizing plate is not attached to the transparent display panel 110, a problem can occur where the light incident from the outside is reflected by electrodes.

In the transparent display panel 110 according to one example embodiment of the present disclosure, since the polarizing plate is not attached, a decrease in transmittance can be prevented. In addition, in the transparent display panel 110 according to one example embodiment of the present disclosure, since the color filter CF is formed, the color filter CF can absorb a part of the light incident from the outside so that the light incident from the outside can be prevented from being reflected by the electrodes. For example, the transparent display panel 110 according to one example embodiment of the present disclosure can reduce the external light reflectance without reducing transmittance.

A black matrix BM can be disposed between the color filters CF patterned for each of the subpixels SP1, SP2, and SP3. The black matrix BM can be disposed between the subpixels SP1, SP2, and SP3 to prevent color mixture from being generated between adjacent subpixels SP1, SP2, and SP3. Further, the black matrix BM can prevent light incident from the outside from being reflected by a plurality of signal lines disposed between the subpixels SP1, SP2, and SP3.

The black matrix BM can be disposed between the transmissive area TA and a plurality of subpixels SP1, SP2, and SP3, and can prevent light emitted from each of a plurality of subpixels SP1, SP2, and SP3 from being propagated to the transmissive area TA. Accordingly, the black matrix BM can define a border between the transmissive area TA and the non-transmissive area NTA. In detail, the black matrix BM can define the border between the non-transmissive area NTA and the transmissive area TA between the emission area EA and the transmissive area TA. In this example, in an area other than the emission area EA, an area in which the black matrix BM is disposed can be the non-transmissive area NTA, and an area in which the black matrix BM is not disposed can be the transmissive area TA. For example, an area in which the emission area EA and the black matrix BM are disposed can be the non-transmissive area NTA, and the remaining area can be the transmissive area TA.

The black matrix BM can include a material that absorbs light, for example, a black dye that absorbs all light in the visible wavelength band.

The first substrate 111 including the color filter CF and the black matrix BM can be bonded to the second substrate 112 by a separate adhesive layer 190. In this example, the adhesive layer 190 can be an optically clear resin layer OCR or an optically clear adhesive film OCA.

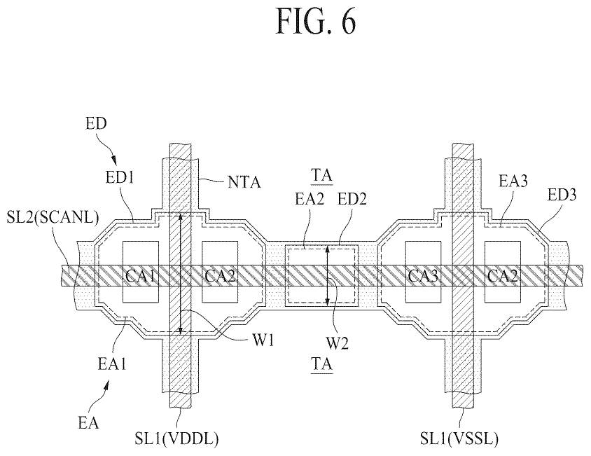

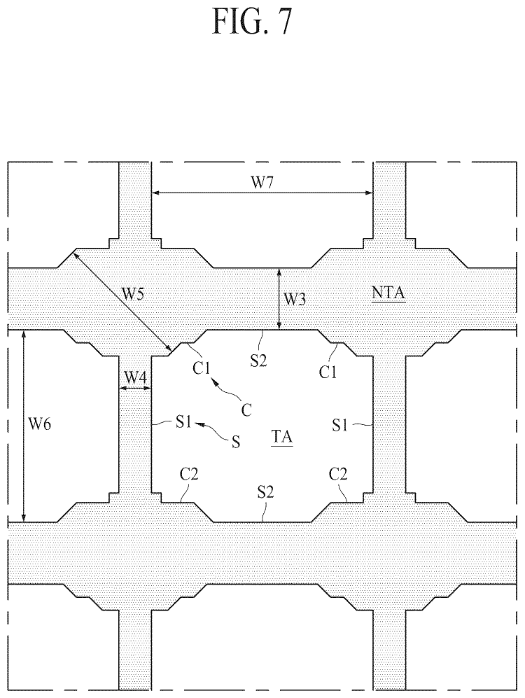

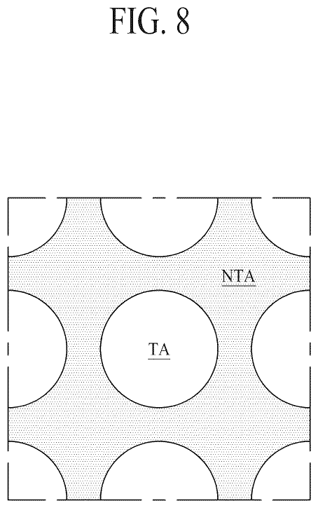

FIG. 6 illustrates an example of a non-transmissive area according to one or more embodiments of the present disclosure, FIG. 7 illustrates an example of a transmissive area according to one or more embodiments of the present disclosure, and FIG. 8 illustrates an example of a circular transmissive area according to aspects of the present disclosure.

Referring to FIGS. 6 and 7, the transparent display panel 110 according to one or more embodiments of the present disclosure includes transmissive areas TA for transmitting external light and a non-transmissive area NTA disposed between the adjacent transmissive areas TA.

The non-transmissive area NTA can include a plurality of emission areas EA that emit light of a predetermined color. The plurality of emission areas EA can include a first emission area EA1 that emits first color light, a second emission area EA2 that emits second color light, and a third emission area EA3 that emits third color light. For example, the first emission area EA1 can emit blue light, the second emission area EA2 can emit red light, and the third emission area EA3 can emit green light.

The light emitting device ED can be disposed in each of the plurality of emission areas EA1, EA2 and EA3. For example, a first light emitting device ED1 that emits blue light can be disposed in the first emission area EA1, a second light emitting device ED2 that emits red light can be disposed in the second emission area EA2, and a third light emitting device ED3 that emits green light can be disposed in the third emission area EA3.

In the non-transmissive area NTA, the first signal line SL1 and the second signal line SL2 can be disposed to overlap with the light emitting devices ED1, ED2, and ED3.

The first signal line SL1 can extend in the first direction (e.g., the Y axis direction) between the first substrate 111 and the light emitting devices ED. The first signal line SL1 can include the pixel power line VDDL and the common power line VSSL. The pixel power line VDDL and the common power line VSSL can be spaced apart from each other with the transmissive area TA interposed therebetween. One pixel power line VDDL or one common power line VSSL can be disposed between the transmissive areas TA adjacent to each other in the second direction (e.g., the X axis direction). The pixel power line VDDL and the common power line VSSL can be alternately disposed with the transmissive area TA interposed therebetween.

The second signal line SL2 can extend in the second direction (e.g., the X axis direction) between the first substrate 111 and the light emitting devices ED. The second signal line SL2 can include the scan line SCANL. One or more scan lines SCANL can be disposed between the transmissive areas TA adjacent to each other in the first direction (e.g., the Y axis direction). The scan line SCANL can include a first scan line SCANL1 and a second scan line SCANL2 (see FIG. 4). The second signal line SL2 can further include an emission control line EML (see FIG. 4).

The first light emitting device ED1, the second light emitting device ED2, and the third light emitting device ED3 can be disposed to overlap with at least one of the first signal line SL1 and the second signal line SL2. The first light emitting device ED1 and the third light emitting device ED3 can be disposed in an area where the first signal line SL1 and the second signal line SL2 are overlapped.

Specifically, each of the first light emitting device ED1 and the third light emitting device ED3 can be disposed in an area where any one of the pixel power line VDDL and the common power line VSSL overlaps with the second signal line SL2. In one example, the first light emitting device ED1 can be disposed in an area where the pixel power line VDDL overlaps with the second signal line SL2, and the third light emitting device ED3 can be disposed in an area where the common power line VSSL overlaps with the second signal line SL2.

The first light emitting device ED1 and the third light emitting device ED3 can be alternately disposed along the pixel power line VDDL, or alternately disposed along the common power line VSSL. In this example, in the first horizontal line, the first light emitting device ED1 can be disposed in an area where the pixel power line VDDL and the second signal line SL2 are overlapped, and the third light emitting device ED3 can be disposed in an area where the common power line VSSL and the second signal line SL2 are overlapped. In the second horizontal line next the first horizontal line, the first light emitting device ED1 can be disposed in an area where the common power line VSSL and the second signal line SL2 are overlapped, and the third light emitting device ED3 can be disposed in an area where the pixel power line VDDL and the second signal line SL2 are overlapped.

The second light emitting device ED2 can be disposed between the first light emitting device ED1 and the third light emitting device ED3. The second light emitting device ED2 can be disposed in an area where the second signal line SL2 is disposed between the first signal lines SL1 adjacent to each other. The second light emitting device ED2 can be disposed in an area where the second signal line SL2 is disposed between the pixel power line VDDL and the common power line VSSL disposed adjacent to each other.

The first light emitting device ED1 and the third light emitting device ED3 can have a relatively large light emitting area in an area where the first signal line SL1 and the second signal line SL2 cross each other. On the other hand, the second light emitting device ED2 can be formed to have a small area between the first light emitting device ED1 and the third light emitting device ED3.

For example, the first light emitting device ED1 and the third light emitting device ED3 can have a relatively large first area, and the second light emitting device ED2 can have a second area smaller than those of the first light emitting device ED1 and the third light emitting device ED3. In addition, the first light emitting device ED1 and the third light emitting device ED3 can have a first width W1 in the first direction (e.g., the Y axis direction), and the second light emitting device ED2 can have a second width W2 smaller than those of the first light emitting device ED1 and the third light emitting device ED3.

In the transparent display panel 110, since the non-transmissive area NTA has a small area, the circuit element can be disposed to overlap with the emission areas EA1, EA2 and EA3. Particularly, in the transparent display panel 110, the driving element for driving the light emitting device ED can be disposed to overlap with the emission areas EA1, EA2 and EA3. The driving element can include the driving transistor DT and the capacitor Cst (see FIG. 4).

For example, a circuit area can include a first circuit area CA1 in which the first driving element connected to the first light emitting device ED1 is disposed, a second circuit area CA2 in which the second driving element connected to the second light emitting device ED2 is disposed, and a third circuit area CA3 in which the third driving element connected to the third light emitting device ED3 is disposed.

In the transparent display panel 110 according to one or more embodiments of the present disclosure, the first to third circuit areas CA1, CA2, and CA3 can be disposed to overlap the first and third light emitting devices ED1 and ED3 having relatively large light emitting areas. Specifically, each of the first to third circuit areas CA1, CA2, and CA3 can overlap any one of the first and third light emitting devices ED1 and ED3. Each of the first to third circuit areas CA1, CA2, and CA3 cannot overlap with the second light emitting device ED2.

As shown in FIG. 6, the first circuit area CAL can overlap with the first light emitting device ED1. The first driving element disposed in the first circuit area CA1 can overlap with the first light emitting device ED1. The first driving element can be disposed on one side of the first signal line SL1 to be electrically connected to the first light emitting device ED1.

The third circuit area CA3 can overlap with the third light emitting device ED3. The third driving element disposed in the third circuit area CA3 can overlap with the third light emitting device ED3. The third driving element can be disposed on one side of the first signal line SL1 to be electrically connected to the third light emitting device ED3.

The second circuit area CA2 can overlap with one of the first light emitting device ED1 and the third light emitting device ED3. The second driving element disposed in the second circuit area CA2 can be disposed on the other side of the first signal line SL1 overlapping the first light emitting device ED1 to be electrically connected to the second light emitting device ED2. Alternatively, the second driving element disposed in the second circuit area CA2 can be disposed on the other side of the first signal line SL1 overlapping the third light emitting device ED3 to be electrically connected to the second light emitting device ED2.

In the transparent display panel 110 according to one example embodiment of the present disclosure, the second width W2 of the second light emitting device ED2 can be reduced by disposing the first to third driving elements to overlap the first light emitting device ED1 and the third light emitting device ED3.

The transmissive area TA is an area through which most external light is transmitted. The light emitting device ED, the circuit element, and the signal lines SL1 and SL2 are not disposed in the transmissive area TA. Further, the transmissive area TA does not overlap the color filter CF (see FIG. 5) and the black matrix BM (see FIG. 5).

As shown in FIG. 7, the transmissive area TA can include a plurality of straight portions S and a plurality of corner portions C.

The plurality of straight portions S can be a straight line extending long while facing each of the first signal line SL1 and the second signal line SL2. The plurality of straight portions S can include a first straight portion S1 facing the first signal line SL1 and a second straight portion S2 facing the second signal line SL2. The plurality of straight portions S can include two first straight portions S1 facing each other and two second straight portions S2 facing each other.

A second light emitting device ED2 (see FIG. 6) can be disposed between the second straight portions S2 of the transmissive areas TA adjacent to each other in the first direction (e.g., the Y axis direction). In the transparent display panel 110 according to one or more embodiments of the present disclosure, the second light emitting device ED2 can have a small width W2 in the first direction (e.g., the Y axis direction) by disposing the second driving element to overlap with the first light emitting device ED1 or the third light emitting device ED3. Accordingly, the non-transmissive area NTA disposed between the second straight portions S2 of the transmissive areas TA adjacent to each other in the first direction (e.g., the Y axis direction) can also have a small width W3.

In the transparent display panel 110 according to one or more embodiments of the present disclosure, the area of the non-transmissive area NTA can be reduced by reducing the width W3 of the non-transmissive area NTA disposed between the second straight portions S2 of the transmissive areas TA, and further the area of the transmissive area TA can be increased. Accordingly, the transparent display panel 110 according to one or more embodiments of the present disclosure can improve the light transmittance of the display area DA.

Further, In the transparent display panel 110 according to one or more embodiments of the present disclosure, the transparent purity can be improved by reducing the width W3 of the non-transmissive area NTA disposed between the second straight portions S2 of the transmissive areas TA. In this example, the transparent purity can represent a degree to which a user clearly recognizes an object or a background scene located on a rear surface of the transparent display panel 110 through the transmissive area TA of the transparent display panel 110. The transparency purity can be determined by the degree of diffraction generated by the non-transmissive area NTA disposed periodically in the transparent display panel 110. When the degree of diffraction increases, the transparency purity decreases, and when the degree of diffraction decreases, the transparency purity can increase. The degree of diffraction can be determined by the width of the non-transmissive area NTA disposed between the adjacent transmissive areas TA. As the width of the non-transmissive area NTA disposed between the adjacent transmissive areas TA decreases, the width within one transmissive area TA increases, and thus the degree of diffraction can decrease.

In the transparent display panel 110 according to one example embodiment of the present disclosure, the third width W3 of the non-transmissive area NTA disposed between the second straight portions S2 of the adjacent transmissive areas TA can be reduced, and thus the sixth width W6 between the second straight portions S2 facing each other in one transmissive area TA can be increased. In the transparent display panel 110 according to one example embodiment of the present disclosure, the degree to which the light passing through the transmissive area TA is diffracted between the second straight portions S2 can be reduced.

In the transparent display panel 110 according to one or more embodiments of the present disclosure, since the side of the transmissive area TA facing the second signal line SL2 is formed in a straight line, the third width W3 of the non-transmissive area NTA can be formed to be constant. For example, in the transparent display panel 110 according to one or more embodiments of the present disclosure, the third width W3 of the non-transmissive area NTA disposed between the second straight portions S2 of the adjacent transmissive areas TA cannot be changed and can be constant. The light passing between the second straight portions S2 facing each other in one transmissive area TA can have similar degrees of diffraction or the degrees of diffraction can be unchanged. In the transparent display panel 110 according to one or more embodiments of the present disclosure, the degree of diffraction of the external light passing through the transmissive area TA between the second straight portions S2 is small and a deviation in the degree of diffraction is not large or does not occur, thereby improving transparent purity.

The light emitting device cannot be disposed between the first straight portions S1 of the transmissive areas TA adjacent to each other in the second direction (e.g., the X axis direction). Accordingly, the non-transmissive area NTA disposed between the first straight portions S1 of the transmissive areas TA adjacent to each other in the second direction (e.g., the X axis direction) can have a fourth width W4 smaller than the third width W3.

In the transparent display panel 110 according to one or more embodiments of the present disclosure, by reducing the fourth width W4 of the non-transmissive area NTA disposed between the first straight portions S1 of the transmissive areas TA, the area of the non-transmissive area NTA can be reduced and further the area of the transmissive area TA can be increased. Accordingly, In the transparent display panel 110 according to one or more embodiments of the present disclosure, the light transmittance of the display area DA can be improved.

Furthermore, In the transparent display panel 110 according to one or more embodiments of the present disclosure, by reducing the fourth width W4 of the non-transmissive area NTA disposed between the first straight portions S1 of the transmissive areas TA, the transparency purity can be increased. Specifically, In the transparent display panel 110 according to one or more embodiments of the present disclosure, the fourth width W4 of the non-transmissive area NTA disposed between the first straight portions S1 of the adjacent transmissive areas TA can be decreased, and thus a seventh width W7 between the first straight portions S1 facing each other in one transmissive area TA can be increased. Accordingly, in the transparent display panel 110 according to one or more embodiments of the present disclosure, the degree to which the light passing through the transmissive area TA is diffracted between the first straight portions S1 can be reduced.

Furthermore, in the transparent display panel 110 according to one or more embodiments of the present disclosure, since the side of the transmissive area TA facing the first signal line SL1 is formed in a straight line, the fourth width W4 of the non-transmissive area NTA can be formed to be constant. For example, in the transparent display panel 110 according to one or more embodiments of the present disclosure, the fourth width W4 of the non-transmissive area NTA disposed between the first straight portions S1 of the adjacent transmissive areas TA cannot be changed and can be constant. The light passing between the first straight portions S1 facing each other in one transmissive area TA can have similar degrees of diffraction or the degrees of diffraction cannot be changed. In the transparent display panel 110 according to one or more embodiments of the present disclosure, since a degree of diffraction of the light passing through the transmissive area TA between the first straight portions S1 is small and a deviation in the degree of diffraction is not large, transparency purity can be increased.

Each of the plurality of corner portions C connects the straight portions S. In this example, each of the plurality of corner portions C can have a step shape in plan view. The plurality of corner portions C can have a step shape while facing an area where the first signal line SL1 and the second signal line SL2 are overlapped.

The plurality of corner portions C can have an asymmetric shape with respect to the center of the first straight portion S1. Specifically, the plurality of corner portions C can include a first corner portion C1 connected to one end of the first straight portion S1 and a second corner portion C2 connected to the other end of the first straight portion S1. The first corner portion C1 and the second corner portion C2 can have an asymmetric shape with respect to the center of the first straight portion S1, but are not limited thereto.

The first and third light emitting devices ED1 and ED3 can be disposed between the corner portions C of the adjacent transmission areas TA. The driving elements do not overlap the second light emitting device ED2, but can overlap with the first and third light emitting devices ED1 and ED3. Accordingly, the first to third driving elements can be disposed between the corner portions C of the adjacent transmission areas TA.

There is a fifth width W5 between the corner portions C of transmissive areas TA adjacent in a third direction (e.g., a diagonal direction) between the first direction (e.g., the Y axis direction) and the second direction (e.g., the X axis direction). The fifth width W5 can be larger than the third width W3 between the second straight portions S2 of the adjacent transmissive areas TA and the fourth width W4 between the first straight portions S1 of the adjacent transmissive areas TA. Accordingly, since the fifth width W5 between the corner portions C of the adjacent transmission areas TA is the largest, it can have the greatest effect on the degree of diffraction of the light passing through the transmissive area TA.

In the transparent display panel 110 according to one or more embodiments of the present disclosure, since the corner portion C of the transmissive area TA can be formed in a step shape, thereby preventing an unnecessary increase in the non-transmissive area NTA. As shown in FIG. 8, when the transmissive area TA is formed in a circular shape, an area formed as the non-transmissive area NTA can occur even though a signal line, a circuit element, or a light emitting device is not disposed at the corner portion. In the transparent display panel 110 according to one or more embodiments of the present disclosure, the area of the non-transmissive area NTA can be minimized by forming the corner portion C of the transmissive area TA in a step shape along the outer periphery of the signal line, the circuit element, or the light emitting device. Furthermore, in the transparent display panel 110 according to one or more embodiments of the present disclosure, the fifth width W5 between the corner portions C of the adjacent transmissive areas TA can be also minimized. Accordingly, in the transparent display panel 110 according to one or more embodiments of the present disclosure, the degree to which the external light passing through the transmissive area TA is diffracted between the corner portions C can be reduced.

In addition, each of the corner portions C of the transmissive area TA can be formed by connecting a plurality of straight lines instead of a curved line. In the transparent display panel 110 according to one or more embodiments of the present disclosure, since the corner portions C of the transmissive area TA are formed of straight lines, the variation amount of the fifth width W5 of the non-transmissive area NTA can be smaller than that of the case where the corner portions C of the transmissive area NTA are formed of a curved line as shown in FIG. 8. For example, in the transparent display panel 110 according to one or more embodiments of the present disclosure, a change in the fifth width W5 of the non-transmissive area NTA can be small between the corner portions C of the adjacent transmissive areas TA. The degree of diffraction of the light passing between the corner portions C facing each other in one transmissive area TA cannot be significantly changed. In the transparent display panel 110 according to one or more embodiments of the present disclosure, the degree of diffraction between the corner portions C that have the greatest influence on the degree of diffraction of the light passing through the transmissive area TA is minimized, and the deviation in the degree of diffraction is also minimized, thereby effectively increasing the transparency purity.

In accordance with aspects of the present disclosure, by disposing the driving elements in the first and third sub-pixels having a relatively large light emitting area, the width of the non-transmissive area disposed between the first and third sub-pixels can be reduced, thereby increasing the area of the transmissive area and improving the light transmittance.

Moreover, in accordance with aspects of the present disclosure, as the width of the non-transmissive area disposed between the first and third sub-pixels decreases, the degree to which the light passing through the transmissive area is diffracted can be reduced.

Moreover, in accordance with aspects of the present disclosure, since the side of the transmissive area facing the non-transmissive area disposed between the first and third sub-pixels is a straight portion, the width of the non-transmissive area can be constant. Accordingly, since the degree of diffraction of the external light passing through the transmissive area between the straight portions is small and the deviation of the degree of diffraction is not large or does not occur, transparent purity can be improved.

Moreover, in accordance with aspects of the present disclosure, by forming the corner portions of the transmissive area to have a step shape, the area of the non-transmissive area disposed between the corner portions of the adjacent transmissive areas can be minimized. Further, by minimizing the width between the corner portions of the transmissive areas adjacent in the diagonal direction, the degree to which external light passing through the transmissive area is diffracted between the corner portions can be reduced.

Moreover, in accordance with aspects of the present disclosure, since the corner portions of the transmissive region are formed by connecting a plurality of straight lines instead of curved lines, a change in the width of the non-transmissive area between the corner portions of the adjacent transmissive areas can be small. Accordingly, the degree of diffraction of external light passing through the transmissive area between the corner portions that have the greatest influence on the degree of diffraction can be minimized, the deviation of the degree of diffraction can be minimized, the transparent purity can be maximized, and the quality of the transparent display panel can be improved.

Moreover, in accordance with aspects of the present disclosure, since the transparent quality of a product can be improved, the yield of the product can be increased, the manufacturing process cost can be reduced, the manufacturing process time can be shortened, and the production energy can be reduced. Further, in the present disclosure, the generation of greenhouse gases due to the manufacturing process can be reduced, thereby implementing ESG (Environment/Social/Governance).

The above-described features, structures, and effects of the present disclosure are included in at least one embodiment of the present disclosure, but are not limited to only one embodiment. Furthermore, the features, structures, and effects described in at least one embodiment of the present disclosure can be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the disclosure and the claims, but should be construed to include all possible embodiments along with the full scope of equivalents to which such claims are entitled. Accordingly, the claims are not limited by the disclosure.

What is claimed is:

1. A transparent display device, comprising:
a substrate including transmissive areas configured to transmit an external light and a non-transmissive area disposed between adjacent transmissive areas; and
a light emitting device disposed in the non-transmissive area on the substrate,
wherein each of the transmissive areas comprises a plurality of straight portions and a plurality of corner portions connecting the plurality of straight portions, and
wherein each of the plurality of corner portions has a step shape in plan view.

2. The transparent display device of claim 1, further comprising:
a first signal line extended in a first direction in the non-transmissive area; and
a second signal line extended in a second direction in the non-transmissive area, the second direction different from the first direction,
wherein the light emitting device comprises:
a first light emitting device disposed in an area where the first signal line and the second signal line are overlapped; and
a second light emitting device disposed in an area where the second signal line is disposed between two adjacent first signal lines.

3. The transparent display device of claim 2, wherein the first light emitting device is disposed between the corner portions of adjacent transmissive areas.

4. The transparent display device of claim 2, wherein the first light emitting device has a first light emitting area, and
wherein the second light emitting device has a second light emitting area that is smaller than the first light emitting area.

5. The transparent display device of claim 2, wherein the first light emitting device has a first width in the first direction, and
wherein the second light emitting device has a second width smaller than the first width in the first direction.

6. The transparent display device of claim 2, wherein the second light emitting device is disposed between the straight portions of adjacent transmissive areas.

7. The transparent display device of claim 2, wherein the second light emitting device emits red light.

8. The transparent display device of claim 2, further comprising driving elements disposed between the substrate and the light emitting device,
wherein the driving elements overlap with the first light emitting device and are spaced apart from the second light emitting device.

9. The transparent display device of claim 8, wherein the driving elements comprise:
a first driving element disposed on a first side of the first signal line in an area overlapping the first light emitting device, the first driving element being electrically connected to the first light emitting device; and
a second driving element disposed on a second side of the first signal line in the area overlapping the first light emitting device, the second driving element being electrically connected to the second light emitting device.

10. The transparent display device of claim 1, wherein the corner portions of one of the transmissive areas are formed by connecting a plurality of straight lines.

11. The transparent display device of claim 1, further comprising:
a first signal line extended in a first direction in the non-transmissive area; and
a second signal line extended in a second direction in the non-transmissive area, the second direction different from the first direction,
wherein the straight portions of one of the transmissive areas comprise a first straight portion facing the first signal line and a second straight portion facing the second signal line,
wherein the light emitting device is not disposed between first straight portions of the transmissive areas adjacent in the second direction, and
wherein the light emitting device is disposed between second straight portions of the transmissive areas adjacent in the first direction.

12. The transparent display device of claim 11, wherein the non-transmissive area disposed between the second straight portions of the transmissive areas adjacent in the first direction has a third width, and
wherein the non-transmissive area disposed between the first straight portions of the transmissive areas adjacent in the second direction has a fourth width smaller than the third width.

13. The transparent display device of claim 11, wherein the corner portions of the one of the transmissive areas comprise a first corner portion connected to one end of the first straight portion and a second corner portion connected to another end of the first straight portion, and
wherein the first corner portion and the second corner portion have an asymmetrical shape with respect to a center of the first straight portion.

14. The transparent display device of claim 1, further comprising:
a color filter disposed on the light emitting device; and
a black matrix disposed on at least one side of the color filter,
wherein one of the transmissive areas does not overlap with the color filter and the black matrix.

15. The transparent display device of claim 1, wherein widths between the corner portions of the transmissive areas adjacent in a diagonal direction of the substrate are minimized.

16. A transparent display device, comprising:
transmissive areas configured to transmit an external light and a non-transmissive area disposed between adjacent transmissive areas;
a first signal line extended in a first direction in the non-transmissive area; and
a second signal line extended in a second direction in the non-transmissive area, the second direction different from the first direction,
wherein each of the transmissive areas comprises:
a plurality of straight portions disposed to face each of the first signal line and the second signal line; and
a plurality of corner portions disposed to have a step shape in plan view while facing an area where the first signal line and the second signal line are overlapped.

17. The transparent display device of claim 16, wherein the first signal line comprises a pixel power line and a common power line spaced apart from the pixel power line with the transmissive area interposed therebetween, and
wherein the transparent display device further comprises:
a first light emitting device disposed in an area where the pixel power line and the second signal line are overlapped;
a third light emitting device disposed in an area where the common power line and the second signal line are overlapped; and
a second light emitting device disposed between the first light emitting device and the third light emitting device.

18. The transparent display device of claim 17, further comprising:
a first driving element electrically connected to the first light emitting device;
a second driving element electrically connected to the second light emitting device; and
a third driving element electrically connected to the third light emitting device,
wherein the first to third driving elements are disposed between the corner portions of adjacent transmissive areas.

19. The transparent display device of claim 18, wherein the first driving element is disposed in an area overlapping the first light emitting device,
wherein the third driving element is disposed in an area overlapping the third light emitting device, and
wherein the second driving element is disposed in an area overlapping the first light emitting device or the third light emitting device.

20. The transparent display device of claim 17, wherein the first light emitting device and the third light emitting device have a first width in the first direction, and
wherein the second light emitting device has a second width smaller than the first width in the first direction.

21. The transparent display device of claim 17, wherein the first light emitting device and the third light emitting device are disposed between the corner portions of adjacent transmissive areas.

22. The transparent display device of claim 17, wherein the second light emitting device is disposed between the straight portions of adjacent transmissive areas.

23. A transparent display device, comprising:
transmissive areas configured to transmit an external light;
a non-transmissive area disposed between adjacent transmissive areas; and
a first sub-pixel, a second sub-pixel and a third sub-pixel disposed in the non-transmissive area,
wherein each of the transmissive areas comprises a plurality of straight portions and a plurality of corner portions connecting the plurality of straight portions, each corner portion having a step shape in plan view, and
wherein a side of each of the transmissive areas facing the non-transmissive area disposed between the first sub-pixel and the third sub-pixel is a straight portion.

24. The transparent display device of claim 23, wherein the first sub-pixel emits a light of a first color, a second sub-pixel emits a light of a second color, and a third sub-pixel emits a light of a third color.
